(19) United States
(12) Patent Application Publication
(10) Pub. No.: US 2012/0088371 A1
(43) Pub. Date: Apr. 12, 2012

(54) METHODS FOR ETCHING SUBSTRATES USING PULSED DC VOLTAGE

(75) Inventors: ALOK RANJAN, Slingerlands, NY (US); NICOLAS GANI, San Jose, CA (US); MEIHUA SHEN, Fremont, CA (US); ANISUL H. KHAN, Santa Clara, CA (US)

(73) Assignee: APPLIED MATERIALS, INC., Santa Clara, CA (US)

(21) Appl. No.: 13/089,374

(22) Filed: Apr. 19, 2011

Related U.S. Application Data
(60) Provisional application No. 61/390,742, filed on Oct. 7, 2010.

(51) Int. Cl. H01L 21/3065

(52) U.S. Cl. 438/711; 438/710; 257/E21.218

(57) ABSTRACT

Methods for etching substrates using a pulsed DC voltage are provided herein. In some embodiments, a method for method for etching a substrate disposed on a substrate support within a process chamber may include providing a process gas to the process chamber; forming a plasma from the process gas; applying a pulsed DC voltage to a first electrode disposed within the process chamber; and etching the substrate while applying the pulsed DC voltage.

### CROSS-REFERENCE TO RELATED APPLICATIONS

This application claims benefit of U.S. provisional patent application Ser. No. 61/390,742, filed Oct. 7, 2010, which is herein incorporated by reference.

### FIELD

Embodiments of the present invention generally relate to semiconductor processing.

### BACKGROUND

One challenge of fabricating, or etching, high aspect ratio features is the ability to etch the feature while maintaining a uniform profile of the feature. In some conventional plasma etching processes a negative DC voltage may be provided to an electrode disposed within a process chamber to facilitate etching such high aspect ratio features. By providing a negative DC voltage, a high energy (non-collisional) electron beam may be created that strikes the substrate surface, thereby enhancing the etching properties by improving the etch selectivity between the materials to be etched and materials and the patterned mask layer. In addition, electrons from the electron beam may neutralize a positive charge build-up at feature-bottom due to bombardment of ions formed in the plasma. However, when providing a constant negative DC voltage, the electrons may not reach the bottom of the features for a portion of the RF cycle (e.g. when a potential of a substrate electron sheath is higher than the potential of an electrode electron sheath), thereby only partially neutralizing the positive charge build up, which may which may lead to damage of the feature due to an overcharging of the feature bottom.

Therefore, the inventors have provided an improved method of etching substrates using a pulsed DC voltage.

### SUMMARY

Methods for etching substrates using a pulsed DC voltage are provided herein. In some embodiments, a method for etching a substrate disposed on a substrate support within a process chamber may include providing a process gas to the process chamber; forming a plasma from the process gas; applying a pulsed DC voltage to a first electrode disposed within the process chamber; and etching the substrate while applying the pulsed DC voltage.

In some embodiments, the methods of the present invention may be embodied in a computer readable medium. The computer readable medium includes instructions stored thereon that, when executed by the controller, causes a dual chamber processing system comprising a first process chamber and a second process chamber that share resources to perform a method for processing substrates, wherein the method may include providing a process gas to the process chamber; forming a plasma from the process gas; applying a pulsed DC voltage to a first electrode disposed within the process chamber; and etching the substrate while applying the pulsed DC voltage.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a method for etching a substrate using a pulsed DC voltage in accordance with some embodiments of the present invention.

FIGS. 2A-B are illustrative cross-sectional views of a substrate during different stages of the method of FIG. 1 in accordance with some embodiments of the present invention.

FIG. 3 is a graph depicting pulsing of DC voltage in accordance with some embodiments of the present invention.

FIG. 4 is a process chamber suitable for performing a method for etching a substrate disposed on a substrate support within a process chamber in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

The inventors have observed that when etching high aspect ratio features only high energy ions reach the bottom of the features being etched, which may lead to damage of the feature due to an overcharging of the feature bottom. Embodiments of the present invention provide methods for etching substrates using pulsed DC voltage. The inventive methods may advantageously allow for a high energy ion flux and electron flux to be controlled during etching processes, thereby reducing or eliminating overcharging of a feature bottom, thus reducing or eliminating any damage due to the overcharging phenomenon.

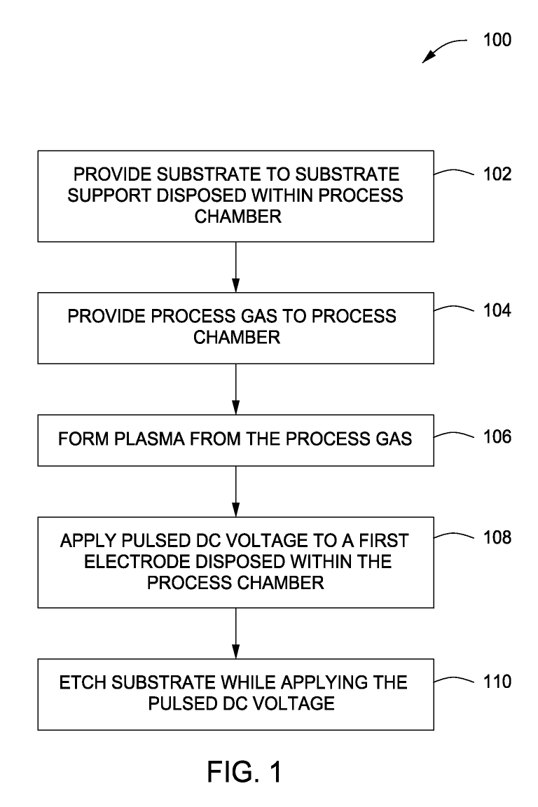

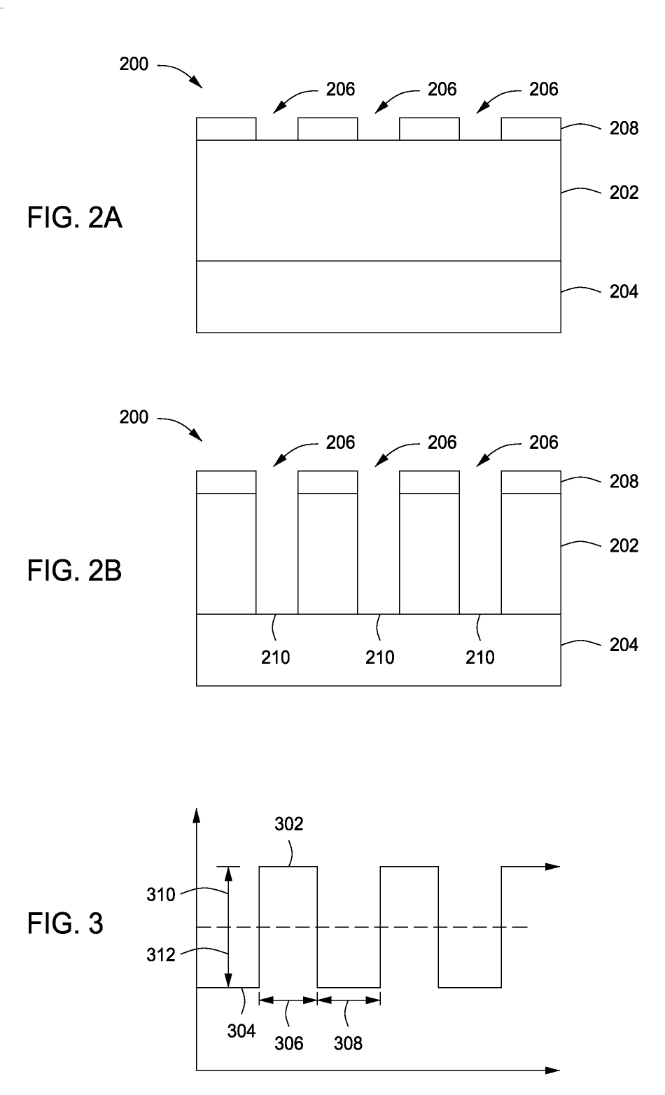

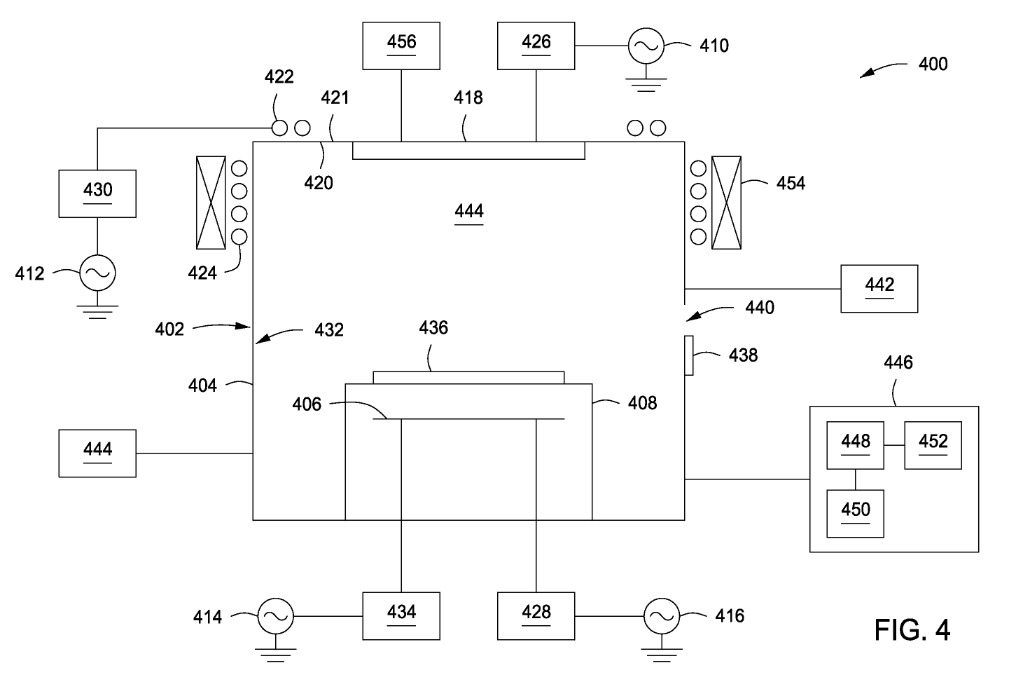

FIG. 1 is a flow diagram of a method 100 for etching a substrate using a pulsed DC voltage in accordance with some embodiments of the present invention. FIGS. 2A-B are illustrative cross-sectional views of a substrate during different stages of the processing sequence of FIG. 1 in accordance with some embodiments of the present invention. The above method may be performed in any apparatus suitable for processing substrates in accordance with embodiments of the present invention, such as discussed below with respect to FIG. 4.

The method 100 generally begins at 102 where a substrate 204 is provided to a substrate support within a process chamber, as depicted in FIG. 2A. The substrate 204 may be any suitable substrate to be etched, such as a doped or un-doped silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a light emitting diode (LED) substrate, a solar cell array, solar panel, or the like. In some embodiments, the substrate 204 may be a semiconductor wafer.

In some embodiments, the substrate 204 may comprise one or more layers 202 (one layer shown) disposed thereon. The one or more layers 202 may be deposited in any suitable manner, such as by electroplating, chemical vapor deposition (CVD), physical vapor deposition (PVD), atomic layer deposition (ALD), or the like. The one or more layers 202 may be any layers suitable for a particular device being fabricated. For example, in some embodiments, the one or more layers 202 may comprise one or more dielectric layers. In such embodiments, the one or more dielectric layers may comprise silicon oxide (SiO₂), silicon nitride (SiN), a low-k material, a high-k material, or the like. As used herein, low-k materials are materials having a dielectric constant less than about that of silicon oxide (SiO₂), which is about 3.9. Accordingly, high-k materials are materials having a dielectric constant greater than silicon oxide (e.g., greater than about 3.9). In embodiments where the dielectric layer comprises a low-k material, the low-k material may be any low-k material, for example such as carbon-doped dielectric materials (such as carbon-doped silicon oxide (SiOC), BLACK DIAMOND® dielectric material available from Applied Materials, Inc. of Santa Clara, Calif., or the like), an organic polymer (such as polyimide, parylene, or the like), organic doped silicon glass (OSG), fluorine doped silicon glass (FSG), or the like. In embodiments where the dielectric layer is a high-k material, the high-k material may comprise any high-k material, for example such as silicon oxide (SiO₂), hafnium oxide (HfO₂), zirconium oxide (ZrO₂), hafnium silicate (HfSiO), or aluminum oxide (Al₂O₃), or the like.

Alternatively, or in combination, in some embodiments, the one or more layers 202 may comprise one or more layers 202 of a conductive material, for example such as a metal. In such embodiments, the metal may comprise copper (Cu), aluminum (Al), tungsten (W), titanium (Ti), alloys thereof, combinations thereof, or the like.

In some embodiments, a patterned mask layer 208 may define one or more features 206 to be etched into the one or more layers 202 and/or substrate 204. In some embodiments, the one or more features 206 to be etched may be high aspect ratio features, wherein the one or more feature 206 comprise an aspect ratio of greater than about 10:1. The patterned mask layer 208 may be any suitable mask layer such as a hard mask, photoresist layer, or combinations thereof. For example, in embodiments where the patterned mask layer 208 is a hard mask, the patterned mask layer 208 may comprise at least one of oxides, such as silicon dioxide (SiO₂), silicon oxynitride (SiON), or the like, or nitrides, such as titanium nitride (TiN), silicon nitride (SiN), or the like, silicides, such as titanium silicide (TiSi), nickel silicide (NiSi) or the like, or silicates, such as aluminum silicate (AlSiO), zirconium silicate (ZrSiO), hafnium silicate (HfSiO), or the like. Alternatively, or in combination, in some embodiments, the mask layer may comprise an amorphous carbon, such as Advanced Patterning Film (APF), available from Applied Materials, Inc., located in Santa Clara, Calif., or a tri-layer resist (e.g., a photoresist layer, a Si-rich anti-reflective coating (ARC) layer, and a carbon-rich ARC, or bottom ARC (BARC) layer), a spin-on hardmask (SOH), or the like. The patterned mask layer 208 may be formed by any process suitable to form a patterned mask layer 208 capable of providing an adequate template for defining the features to be etched into the underlying one or more layers 202. For example, in some embodiments, the patterned mask layer 208 may be formed via an etch process. In some embodiments, for example where the patterned mask layer 208 will be utilized to define advanced or very small node devices (e.g., about 40 nm or smaller nodes, such as Flash memory devices), the patterned mask layer 208 may be formed via a spacer mask patterning technique, such as a self-aligned double patterning process (SADP).

Next, at 104, a process gas may be provided to the process chamber. The process gas may comprise any gases suitable to form a plasma to etch the one or more layers 202 and/or the substrate 204. For example, in some embodiments the process gases may comprise at least one of a hydrofluorocarbon (CxHyFz), a halogen containing gas, oxygen (O₂), nitrogen trifluoride (NF₃), sulfur hexafluoride (SF₆), or the like. The process gas may be provided at any suitable flow rate, for example, such as about 10 to about 1000 sccm.

Optionally, a dilutant/carrier gas may be provided with the process gas. The dilutant gas may be any one or more inert gases, such as nitrogen (N₂), helium (He), argon (Ar), xenon (Xe), or the like. In some embodiments, the dilutant gas may be provided at a flow rate of about 10 to about 1000 sccm.

Next, at 106, a plasma is formed from the process gas. Generally, to form the plasma, the process gas may be ignited into a plasma by coupling RF power from a plasma power source (e.g. one or more of the RF power sources 410, 412, 414, 416 described below with respect to FIG. 4) at a suitable frequency to the process gas within a process chamber under suitable conditions to establish the plasma. For example, in some embodiments, a plasma power source of up to about 3000 W, at a frequency in a range from about 50 KHz to about 162 MHz may be provided to ignite and maintain the plasma. In some embodiments, the plasma power source may be provided via an electrode disposed within the process chamber (e.g., conductor 418 described below), one or more RF induction coils (e.g. induction coils 422, 424 described below), or an electrode disposed within the substrate support (electrode 406 of substrate support 408 described below).

Additional process parameters may be utilized to promote plasma ignition and stability. For example, in some embodiments, the process chamber may be maintained at a temperature of between about 60 to about 100 degrees Celsius during plasma ignition. Additionally, in some embodiments, the process chamber may be maintained at a pressure of between about 4 to about 200 mTorr.

Next, at 108, a pulsed DC voltage is applied to a first electrode disposed within the process chamber. The first electrode may be disposed in any suitable location in an upper portion of the process chamber, generally opposing the substrate support. For example, in some embodiments, the first electrode may be formed as part of a conductive portion of the process chamber ceiling, or as part of a conductive portion of a showerhead or other gas distribution apparatus disposed in or near the process chamber ceiling (e.g., conductor 418 described below). By providing a DC voltage to the first electrode a ballistic (non-collision) electron beam may be created that strikes the substrate surface during a fraction of the RF cycle, thereby enhancing the etching properties by, for example, improving the etch selectivity between the etched materials (one or more layers 202 and/or substrate 204) and the patterned mask layer 208. In some embodiments, a positive charge build up at the feature bottom 210 due to ion bombardment may be at least partially neutralized by provided the DC voltage at a negative voltage. However, the inventors have observed that when etching high aspect ratio features only high energy ions reach the bottom 210 of the features being etched, which leads to damage to the feature from an over charging of the feature bottom 210. Accordingly, the inventors have discovered that by pulsing the DC voltage, the high energy ion flux and electron flux may be controlled, thereby reducing or eliminating over charging of the feature bottom 210, thus reducing or eliminating any damage that may occur as a result of the charging.

The pulsed DC voltage may be provided at any suitable magnitude and pulsed at any frequency suitable to reduce the overcharging of the feature bottom 210 as described above. For example, in some embodiments the DC voltage may be pulsed from a positive voltage 302 to a negative voltage 304, as depicted in FIG. 3. During the time period 306 where the DC voltage is at a positive voltage 302 the plasma potential is increased from a floating potential (e.g. in some embodiments about 25 V) by the magnitude 310 of the positive voltage 302 causing ions to bombard the substrate 204 at an ion energy equal to that of about the magnitude 310 of the positive voltage 302 and a self DC bias formed on the substrate. During the time period 308 where the DC voltage is at a negative voltage 304 the plasma potential is substantially equal to the floating potential, creating a sheath at the DC electrode having a voltage equal to the combined negative voltage 304 magnitude 310 and the floating potential. This sheath causes the ions to bombard the DC electrode, causing secondary electron emissions. The secondary electrons bombard the substrate 204 at an energy increased by a magnitude equal to the negative voltage 304 magnitude 310 and the floating potential. In addition, the plasma density uniformity (e.g., center low to center high) may also be controlled by varying the magnitude 312 of the negative voltage 304. For example, in embodiments where the self bias is substantially equal to the magnitude 312 of the negative voltage 304, the secondary electrons get trapped proximate the central region of the plasma, thereby producing a center high plasma.

In accordance with the above, the inventors have discovered that in some embodiments, the DC voltage in the positive cycle (i.e., positive voltage 302) and the negative cycle (negative voltage 304) may be varied to modulate the ion energy and secondary electron energy bombarding the substrate 204, as described above. In such embodiments, the magnitude 310, 312 of the positive voltage 302 and the negative voltage 304 may be about 100 to about 2000 V. In some embodiments, the time period 306 where the DC voltage is at a positive voltage 302 and the time period 308 where the DC voltage is at a negative voltage 304 may be the same, or in some embodiments, different. In some embodiments, the time periods 306 and 308 may be less than a time necessary to charge the feature bottom 210, to allow the feature bottom 210 charge to reach a steady state value. In some embodiments, each time period 306, 308 may be about 10 micro-seconds to about 10 milliseconds. In some embodiments, the pulse frequency, e.g., the frequency of one “positive voltage 302/negative voltage 304” cycle, may be between about 100 Hz to about 100 kHz.

Returning to FIG. 1, next, at 110, the one or more layers 202 and/or the substrate 204 is etched using the plasma formed from the process gas while applying the pulsed DC voltage (described above) to form one or more features 206, as depicted in 2B. Generally, to facilitate etching, high energy ions from the plasma are accelerated towards the substrate 204, causing material to be ejected from the one or more layers 202 and/or the substrate 204, thereby etching the one or more features 206. In some embodiments, the ions may be directed toward the substrate 204 via a self bias formed on the substrate 204 resulting from the application of RF power to the process gas to form the plasma or from the DC power applied to the first electrode, as discussed above. Alternatively, or in combination, to facilitate directing the ions towards the substrate 204 additional bias power may be provided to the substrate 204 via a second electrode disposed within the substrate support (e.g., second electrode 406 disposed in substrate support 408 described below). In such embodiments, the bias power may be about 100 to 3000 W, at a frequency of about 2 to about 13.56 MHz, or in some embodiments, about 60 Mhz.

In addition, one or more additional sources of RF power (e.g. RF power sources 414, 416 described below) may be applied to the second electrode at multiple frequencies to provide control over the uniformity of the plasma and plasma density. For example, in such embodiments, the additional bias power may be about 100 to 3000 W, at a frequency of about 13.56 to about 162 MHz.

Additional process parameters may be utilized to facilitate etching the one or more layers 202 and/or the substrate 204. For example, in some embodiments, the process chamber may be maintained at a temperature of about 60 to about 100 degrees Celsius during plasma ignition. Additionally, in some embodiments, the process chamber may be maintained at a pressure of about 4 to about 200 mTorr.

Upon completion of etching the one or more layers 202 and/or the substrate 204 at 108, the process generally ends and the substrate may continue to be processed as desired. For example, in some embodiments, additional etch process may be performed to form the features 206 into additional underlying layers or a deposition process may be performed to fill the features 206.

FIG. 4 depicts a process chamber 400 suitable for performing the above method 100 in accordance with some embodiments of the present invention. The process chamber 400 may be utilized alone or, in some embodiments, as a processing module of an integrated semiconductor substrate processing system, or cluster tool, such as a CENTURA® integrated semiconductor substrate processing system, available from Applied Materials, Inc. of Santa Clara, Calif. Examples of suitable process chambers that may be modified in accordance with some aspects of the present invention include the Decoupled Plasma Source (DPS) line of chambers, a HART™, E-MAX®, ADVANTEDGE™ or ENABLER® etch chamber available from Applied Materials, Inc., of Santa Clara, Calif. Other process chambers, including those from other manufacturers, may be utilized as well.

The process chamber 400 generally comprises walls 404 and a ceiling 420 defining a chamber body 402, and a substrate support 408 disposed within the chamber body 402. In some embodiments, the ceiling 420 may comprise a non-conductive portion 421 and a conductive portion (conductor 418). In such embodiments, the non-conductive portion 421 may be fabricated from quartz (SiO₂). Alternatively, in some embodiments, the entire ceiling 420 may be fabricated from a conductive material. In some embodiments, the conductive walls 404 may be fabricated from highly doped silicon or metal, for example aluminum (Al). In addition, the conductive walls 404 may comprise a coating on its inner surfaces 432 comprising, for example an aluminum/yttria alloy (AL/Y₂O₅).

In some embodiments, the process chamber 400 may utilize capacitively coupled RF power for plasma processing, although the process chambers 400 may also or alternatively use inductive coupling of RF power for plasma processing. For example, the substrate support 408 may have an electrode 406 disposed within the substrate support 408, or a conductive portion of the substrate support 408 may be used as the electrode. The electrode 406 may be coupled to one or more plasma power sources (one RF plasma power source 414) through one or more respective matching networks (one matching network 434 shown). Alternatively, or in combination, in some embodiments, one or more plasma power sources (one RF power source 410 shown) may be coupled to an upper electrode through one or more matching networks (one matching network 426 shown) proximate an upper portion of the process chamber 400. In some embodiments, the upper electrode may be the conductor 418 disposed in the ceiling 420 of the process chamber 400, or in some embodiments, may be the entire ceiling 420. Alternatively, or in combination, in some embodiments, one or more RF plasma power sources 412 may be coupled to inductive coil elements 422, 424 via a one or more matching networks 430 disposed proximate the ceiling 420 or the walls 404 of the process chamber 400 to form a plasma with inductively coupled RF power. The RF plasma power sources 410, 416, 412 may be capable of producing up to 5,000 W at a frequency of up to about 60 MHz.

A DC power source 456 is coupled to the upper electrode (e.g. the conductor 418 or ceiling 420) to provide a pulsed DC power to the process chamber 400 during etch processes, for example, such as the etch process as described above with respect to the inventive method 100.

In some embodiments, the substrate support 408 is coupled, through a matching network 428, to a biasing power source 416. The biasing power source 414 generally is capable of producing up to 5,000 W at a frequency of up to about 13.56 MHz. The biasing power may be either continuous or pulsed power. In some embodiments, additional or alternative biasing power sources may be included, for example a DC or pulsed DC source.

In some embodiments, a magnet 454 may be disposed about the process chamber 400 for selectively providing a magnetic field between the substrate support 408 and the ceiling 410 (or conductor 418 when present). For example, as shown in FIG. 4, the magnet 454 may be disposed about the outside of the process chamber wall 404 in a region above the substrate support 408 when in processing position. In some embodiments, the magnet 454 may be disposed additionally or alternatively in other locations. The magnet 454 may be an electromagnet and may be coupled to a power source (not shown) for controlling the magnitude of the magnetic field generated by the electromagnet.

The substrate 436 may enter the process chamber 400 via an opening 440 in a wall 404 of the process chamber 400. The opening 440 may be selectively sealed via a slit valve 438, or other mechanism for selectively providing access to the interior of the process chamber 400 through the opening 440. The substrate support 408 may be coupled to a lift mechanism (not shown) that may control the position of the substrate support 408 between a lower position suitable for transferring substrates into and out of the chamber via the opening 440 and a selectable upper position suitable for processing. The process position may be selected to maximize process uniformity for a particular process. When in at least one of the elevated processing positions, the substrate support 440 may be disposed above the opening 440 to provide a symmetrical processing region.

One or more gas inlets (not shown) may be coupled to a gas supply 442 for providing one or more process gases into the processing volume 444 of the process chambers 400. A vacuum pump 445 may be coupled to the process chamber 400 via a pumping plenum and pumping port for pumping out exhaust gases from the process chamber 400. The vacuum pump 445 may be fluidly coupled to an exhaust outlet for routing the exhaust as required to appropriate exhaust handling equipment. A valve (such as a gate valve or the like) may be disposed in the pumping plenum to facilitate control of the flow rate of the exhaust gases in combination with the operation of the vacuum pump 445.

To facilitate control of the process chamber 400, a controller 446 may be coupled to the process chamber. The controller 446 may be one of any form of general-purpose computer processor that can be used in an industrial setting for controlling various chambers and sub-processors. The memory, or computer-readable medium 450 of the CPU 448 may be one or more of readily available memory such as random access memory (RAM), read only memory (ROM), floppy disk, hard disk, or any other form of digital storage, local or remote. The support circuits 452 are coupled to the CPU 448 for supporting the processor in a conventional manner. These circuits include cache, power supplies, clock circuits, input/output circuitry and subsystems, and the like.

The inventive methods disclosed herein may generally be stored in the memory, or computer-readable medium 450 as a software routine that, when executed by the CPU 448, causes the process chamber 400 to perform processes of the present invention. The software routine may also be stored and/or executed by a second CPU (not shown) that is remotely located from the hardware being controlled by the CPU 448. Some or all of the method of the present invention may also be performed in hardware. As such, the invention may be implemented in software and executed using a computer system, in hardware as, e.g., an application specific integrated circuit or other type of hardware implementation, or as a combination of software and hardware. The software routine, when executed by the CPU 448, transforms the general purpose computer into a specific purpose computer (controller) 446 that controls the chamber operation such that the methods disclosed herein are performed.

Thus, methods for etching substrates using a pulsed DC voltage are provided herein. The inventive methods may advantageously allow for a high energy ion flux and electron flux to be controlled during etching processes, thereby reducing or eliminating over charging of a feature bottom, thus reducing or eliminating any damage that may occur as a result of the charging.

While the foregoing is directed to embodiments of the present invention, other and further embodiments of the invention may be devised without departing from the basic scope thereof.

1. A method for etching a substrate disposed on a substrate support within a process chamber, comprising:
providing a process gas to the process chamber;
forming a plasma from the process gas;
applying a pulsed DC voltage to a first electrode disposed within the process chamber; and
etching the substrate while applying the pulsed DC voltage.

2. The method of claim 1, wherein pulsing the DC voltage comprises pulsing the DC voltage from a positive voltage to a negative voltage.

3. The method of claim 2, wherein the positive or negative voltage is about 100 to about 2000 V.

4. The method of claim 2, wherein pulsing the DC voltage comprises:
providing the DC voltage at the positive voltage for a first period of time; and
providing the DC voltage at the negative voltage for a second period of time.

5. The method of claim 4, wherein the first period of time and the second period of time each are about 10 micro-seconds to about 10 milliseconds.

6. The method of claim 1, wherein the pulsed DC voltage is pulsed at a frequency of about 100 Hz to about 100 kHz.

7. The method of claim 1, wherein first electrode is disposed within the process chamber and opposes the substrate support.

8. The method of claim 1, further comprising:
applying a first RF energy to a second electrode disposed within the substrate support.

9. The method of claim 8, wherein the first RF energy is provided at a frequency of about 2 to about 13.5 MHz.

10. The method of claim 8, further comprising applying a second RF energy to the second electrode.

11. The method of claim 10, wherein the second RF energy is provided at a frequency of about 13.56 to about 162 MHz.

12. The method of claim 1, further comprising:
applying an RF energy to an inductive coil disposed proximate the first electrode.

13. The method of claim 12, wherein the RF energy is provided at a frequency of about 2 to about 60 MHz.

14. The method of claim 1, further comprising applying an RF energy to the first electrode.

15. The method of claim 1, wherein the RF energy is provided at a frequency of about 2 to about 162 MHz.

16. The method of claim 1, wherein etching the substrate comprises etching one or more features into the substrate having an aspect ratio of greater than about 10:1.

17. A computer readable medium having instructions stored thereon that, when executed by the controller, causes a dual chamber processing system comprising a first process chamber and a second process chamber that share resources to perform a method for processing substrates, the method comprising:
providing a process gas to the process chamber;
forming a plasma from the process gas;
applying a pulsed DC voltage to a first electrode disposed within the process chamber; and
etching the substrate while applying the pulsed DC voltage.

18. The computer readable medium of claim 17, wherein pulsing the DC voltage comprises pulsing the DC voltage from a positive voltage to a negative voltage.

19. The computer readable medium of claim 18, wherein pulsing the DC voltage comprises:
providing the DC voltage at the positive voltage for a first period of time; and
providing the DC voltage at the negative voltage for a second period of time.

20. The computer readable medium of claim 17, wherein the pulsed DC voltage is pulsed at a frequency of about 100 Hz to about 100 kHz.
